(19) United States
(12) Patent Application Publication
(10) Pub. No.: US 2015/0061734 A1
(43) Pub. Date: Mar. 5, 2015

(54) INTERFACE CIRCUIT

(71) Applicant: KABUSHIKI KAISHA TOSHIBA, Tokyo (JP)

(72) Inventors: Yosuke Ogawa, Yokohama-shi (JP); Akira Iwata, Yokohama-shi (JP); Junichiro Noda, Yokohama-shi (JP)

(73) Assignee: KABUSHIKI KAISHA TOSHIBA, Tokyo (JP)

(21) Appl. No.: 14/199,259

(22) Filed: Mar. 6, 2014

(30) Foreign Application Priority Data
Aug. 27, 2013 (JP) 2013-175925

(51) Int. Cl. H03K 17/22; H03K 19/0185; H03L 7/00

(52) U.S. Cl. CPC H03K 17/223; H03K 19/018521
USPC 327/143

(57) ABSTRACT

According to one embodiment, a first pull-down transistor, a mode switching circuit, and a leak-cut circuit are provided. The first pull-down transistor pulls down an input/output terminal. The mode switching circuit controls on and off of the first pull-down transistor based on an enable signal. The leak-cut circuit turns off the first pull-down transistor when a power supply of the mode switching circuit is shut down.

### CROSS-REFERENCE TO RELATED APPLICATIONS

This application is based upon and claims the benefit of priority from Japanese Patent Application No. 2013-175925, filed on Aug. 27, 2013; the entire contents of which are incorporated herein by reference.

### FIELD

Embodiments described herein relate generally to an interface circuit.

### BACKGROUND

In an interface circuit, a plurality of circuit blocks operated by a mutually different power supply voltage is connected to each other in some cases. In such cases, a tolerant function is provided for these circuit blocks in order to set a signal voltage irrespective of the power supply voltage.

### BRIEF DESCRIPTION OF THE DRAWINGS

FIG. 1 is a block diagram illustrating a schematic configuration of a communication apparatus to which an interface circuit according to a first embodiment is applied;

FIG. 2 is a circuit diagram illustrating a schematic configuration of the interface circuit according to the first embodiment;

FIG. 3 is a circuit diagram illustrating a schematic configuration of an interface circuit according to a second embodiment; and

FIG. 4 is a circuit diagram illustrating a schematic configuration of an interface circuit according to a third embodiment.

### DETAILED DESCRIPTION

In general, according to one embodiment, an interface circuit includes a first pull-down transistor, a mode switching circuit, and a leak-cut circuit. The first pull-down transistor pulls down an input/output terminal. The mode switching circuit controls on and off of the first pull-down transistor based on an enable signal. The leak-cut circuit turns off the first pull-down transistor when a power supply of the mode switching circuit is shut down.

Exemplary embodiments of an interface circuit will be explained below in detail with reference to the accompanying drawings. The present invention is not limited to these embodiments.

### First Embodiment

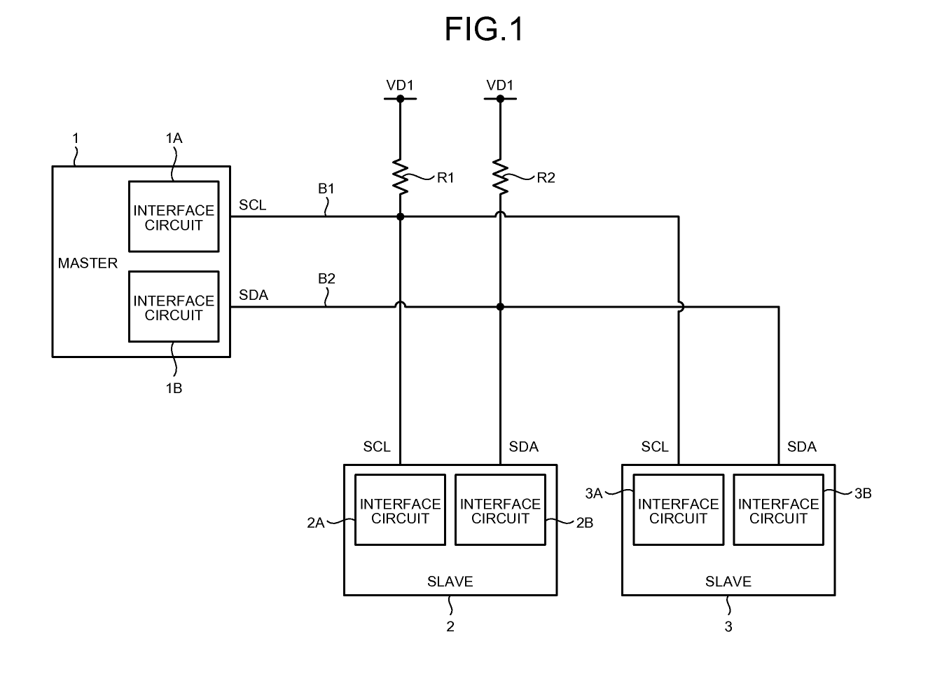

FIG. 1 is a block diagram illustrating a schematic configuration of a communication apparatus to which an interface circuit according to a first embodiment is applied.

In FIG. 1, in this communication apparatus, communication can be performed by an I2C (Inter-Integrated Circuit) system. In the I2C system, serial communication with a rate of 100 kbps or 400 kbps can be performed between the communication apparatus and peripheral devices such as a NAND flash memory that are directly connected within a short distance, such as within a same substrate.

In the I2C system, a signal line B1 that transmits a serial clock SCL and a signal line B2 that transmits serial data SDA are provided. The I2C system is divided into a master 1 that takes control of the system and slaves 2 and 3 that are operated according to the control of the master 1. The master 1 and the slaves 2 and 3 are connected to each other via the signal lines B1 and B2, respectively. The master 1 can communicate with a plurality of slaves 2 and slaves 3. The signal lines B1 and B2 are connected to an external power supply potential VD1 via a resistor R1 and a resistor R2, respectively. For example, the external power supply potential VD1 can be set to approximately 5 V (volts).

Interface circuits 1A and 1B that can set a power supply potential of the master 1 irrespective of the external power supply potential VD1 of the signal lines B1 and B2 are provided in the master 1. The interface circuits 1A and 1B are provided with a tolerant function that prevents a current from flowing to a power supply from an input of the master 1 even when the power supply potential of the master 1 is smaller than the external power supply potential VD1. Interface circuits 2A and 2B that can set a power supply potential of the slave 2 irrespective of the external power supply potential VD1 of the signal lines B1 and B2 are provided in the slave 2. The interface circuits 2A and 2B are provided with a tolerant function that prevents a current from flowing to a power supply from an input of the slave 2 even when the power supply potential of the slave 2 is smaller than the external power supply potential VD1. Interface circuits 3A and 3B that can set a power supply potential of the slave 3 irrespective of the external power supply potential VD1 of the signal lines B1 and B2 are provided in the slave 3. The interface circuits 3A and 3B are provided with a tolerant function that prevents a current from flowing to a power supply from an input of the slave 3 even when the power supply potential of the slave 3 is smaller than the external power supply potential VD1.

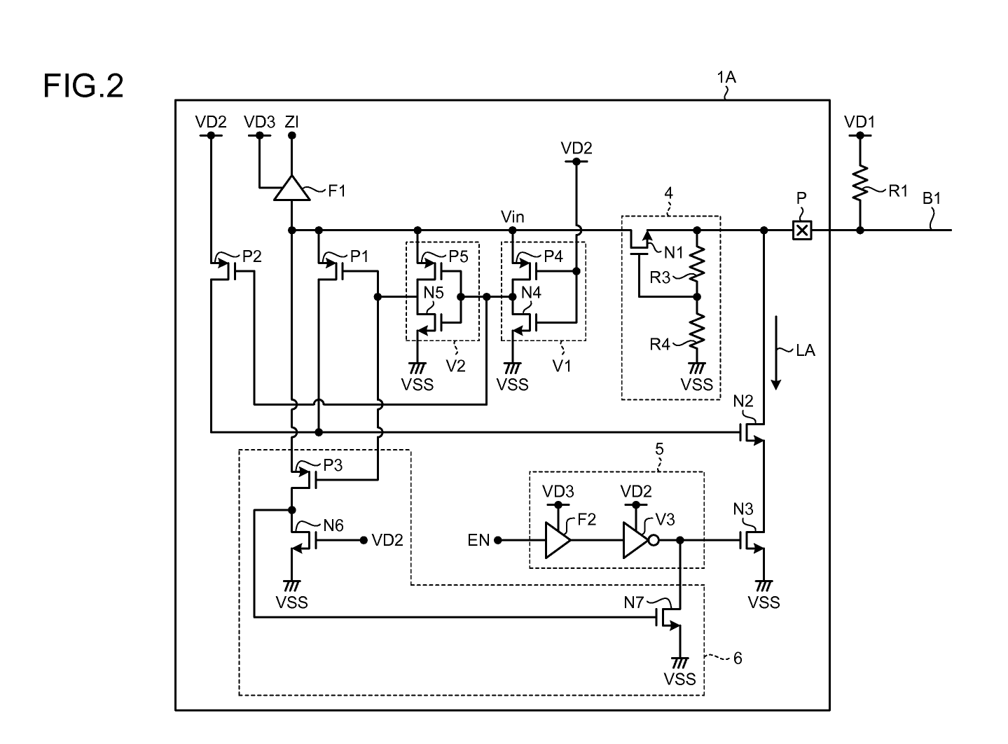

FIG. 2 is a circuit diagram illustrating a schematic configuration of the interface circuit 1A according to the first embodiment.

In FIG. 2, an input/output terminal P is provided in the interface circuit 1A. The input/output terminal P can serve as a pad electrode provided on a semiconductor chip. The input/output terminal P is connected to the signal line B1.

Pull-down transistors N2 and N3 that pull down the input/output terminal P, a self-bias circuit 4, inverters V1 and V2, a buffer F1, control transistors P1 and P2, a mode switching circuit 5, and a leak-cut circuit 6 are provided in the interface circuit 1A. The self-bias circuit 4 is provided with a transfer transistor N1 and resistors R3 and R4. The inverter V1 is provided with a P-type transistor P4 and an N-type transistor N4. The inverter V2 is provided with a P-type transistor P5 and an N-type transistor N5. The mode switching circuit 5 is provided with an inverter V3 and a buffer F2. The leak-cut circuit 6 is provided with control transistors P3 and N6 and a leak-cut transistor N7.

A P-type transistor can be used for the control transistors P1 to P3. An N-type transistor can be used for the transfer transistor N1, the pull-down transistors N2 and N3, the control transistor N6, and the leak-cut transistor N7.

The pull-down transistors N2 and N3 pull down the input/output terminal P. In this example, the pull-down transistors N2 and N3 are connected to each other in series, a drain of the pull-down transistor N2 is connected to the input/output terminal P, and a source of the pull-down transistor N3 is connected to a ground potential VSS.

The self-bias circuit 4 generates an input voltage Vin based on a divided voltage that is generated by dividing an external voltage applied to the input/output terminal P. The external voltage applied to the input/output terminal P can be set equal to or lower than the external power supply potential VD1. In this example, the resistors R3 and R4 are connected to each other in series, and a series circuit of the resistors R3 and R4 is connected between the input/output terminal P and the ground potential VSS. A gate of the transfer transistor N1 is connected to a connection point of the resistors R3 and R4, and a source of the transfer transistor N1 is connected to the input/output terminal P.

The inverters V1 and V2 are connected to each other in series, and power feeding is made from the input voltage Vin to the inverters V1 and V2. An internal power supply potential VD2 is then input to the inverter V1 and an output of the inverter V1 is input to the inverter V2. The internal power supply potential VD2 can be set lower than the external power supply potential VD1 and can be set to approximately 3.3 V, for example.

Power feeding is made from an internal power supply potential VD3 to the buffer F1. The input voltage Vin is then input to the buffer F1 and an output voltage ZI is output from the buffer F1. The internal power supply potential VD3 can be set lower than the internal power supply potential VD2 and can be set to approximately 1.1 V, for example. In this example, the buffer F1 can cause the output voltage ZI to be lower-amplified than the external power supply potential VD1. Therefore, it is possible to realize a higher speed of subsequent circuits of the buffer F1 as well as lower power consumption.

Power feeding is made from the input voltage Vin to the control transistor P1 and the control transistor P1 can turn on the pull-down transistor N2 when the internal power supply potential VD2 is shut down. In this case, a gate of the control transistor P1 is connected to an output of the inverter V2, the input voltage Vin is input to a source of the control transistor P1, and a drain of the control transistor P1 is connected to a gate of the pull-down transistor N2.

Power feeding is made from the internal power supply potential VD2 to the control transistor P2 and the control transistor P2 can turn on the pull-down transistor N2 when the internal power supply potential VD2 is supplied. In this case, a gate of the control transistor P2 is connected to the output of the inverter V1, the internal power supply potential VD2 is input to a source of the control transistor P2, and a drain of the control transistor P2 is connected to the gate of the pull-down transistor N2.

Power feeding is made from the internal power supply potentials VD2 and VD3 to the mode switching circuit 5 and the mode switching circuit 5 controls on and off of the pull-down transistor N3 based on an enable signal EN. The enable signal EN can switch an input mode and an output mode of the interface circuit 1A. In the input mode, the input/output terminal P can be pulled up to the external power supply potential VD1. In the output mode, the input/output terminal P can be pulled down to the ground potential VSS. In this example, power feeding is made from the internal power supply potential VD2 to the inverter V3 and an output of the inverter V3 is connected to a gate of the pull-down transistor N3. Power feeding is made from the internal power supply potential VD3 to the buffer F2, an output of the buffer F2 is connected to an input of the inverter V3, and the enable signal EN is input to the buffer F2.

Power feeding is made from the input voltage Vin to the leak-cut circuit 6 and the leak-cut circuit 6 can turn off the pull-down transistor N3 when the internal power supply potential VD2 is shut down. In this case, the control transistors P3 and N6 are connected to each other in series. The input voltage Vin is input to a source of the control transistor P3 and a gate of the control transistor P3 is connected to the output of the inverter V2. The internal power supply potential VD2 is input to a gate of the control transistor N6. A gate of the leak-cut transistor N7 is connected to a connection point of the control transistors P3 and P6 and a drain of the leak-cut transistor N7 is connected to a gate of the pull-down transistor N3.

Thereafter, an external voltage applied to the input/output terminal P is input to the source of the transfer transistor N1, is divided at the resistors R3 and R4, and the divided voltage is applied to the gate of the transfer transistor N1. Accordingly, a voltage having a threshold voltage of the transfer transistor N1 subtracted from the divided voltage is output from the source of the transfer transistor N1 as the input voltage Vin. Subsequently, the input voltage Vin is output via the buffer F1 as the output voltage ZI.

In this case, because the self-bias circuit 4 generates a bias voltage of the transfer transistor N1 from an external voltage that is applied to the input/output terminal P, even when the internal power supply potential VD2 is shut down, the input voltage Vin can be generated. Furthermore, the self-bias circuit 4 can generate the input voltage Vin by dropping the external voltage that is applied to the input/output terminal P, and it becomes possible to prevent a high voltage corresponding to the external power supply potential VD1 from being applied to the buffer F1. Therefore, the buffer F1 can be protected.

Further, the input voltage Vin is input to sources of the P-type transistors P4 and P5 of the inverters V1 and V2, and is also input to the sources of the control transistors P1 and P3. At this time, when the internal power supply potential VD2 is supplied, the output of the inverter V1 becomes a low level, thereby turning on the control transistor P2. As a result, the internal power supply potential VD2 is applied to the pull-down transistor N2 and a gate potential of the pull-down transistor N2 becomes a high level, thereby turning on the pull-down transistor N2.

Meanwhile, when the internal power supply potential VD2 is shut down, the output of the inverter V1 becomes a high level, and as the output of the inverter V1 is inverted by the inverter V2, the output of the inverter V2 becomes a low level, thereby turning on the control transistor P1. As a result, the input voltage Vin is applied to the pull-down transistor N2 and the gate potential of the pull-down transistor N2 becomes a high level, thereby turning on the pull-down transistor N2.

In the output mode, the enable signal EN is set to be a low level. The enable signal EN then becomes a high level as it is inverted by the inverter V3 and a gate potential of the pull-down transistor N3 becomes a high level, thereby turning on the pull-down transistor N3. Accordingly, the input/output terminal P is pulled down to the ground potential VSS via the pull-down transistors N2 and N3. At this time, when the internal power supply potential VD2 is supplied, the output of the inverter V1 becomes a low level and the output of the inverter V2 becomes a high level as the output of the inverter V1 is inverted by the inverter V2. Accordingly, a gate potential of the control transistor P3 becomes a high level, thereby turning off the control transistor P3. Furthermore, a gate potential of the control transistor N6 becomes a high level, thereby turning on the control transistor N6. Accordingly, the ground potential VSS is applied on a gate of the leak-cut transistor N7 and the leak-cut transistor N7 is turned off, and thus the gate potential of the pull-down transistor N3 can be maintained at a high level.

Meanwhile, in the input mode, the enable signal EN is set to be a high level. When the internal power supply potential VD2 is supplied, the enable signal EN becomes a low level as it is inverted by the inverter V3, thereby turning off the pull-down transistor N3. Accordingly, the input/output terminal P is pulled up to the external power supply potential VD1. In the input mode, when the internal power supply potential VD2 is shut down, the output of the inverter V1 becomes a high level and the output of the inverter V2 becomes a low level as the output of the inverter V1 is inverted by the inverter V2. Accordingly, the gate potential of the control transistor P3 becomes a low level, thereby turning on the control transistor P3. As a result, the input voltage Vin is applied to the gate of the leak-cut transistor N7, thereby turning on the leak-cut transistor N7. Accordingly, the ground potential VSS is applied to the gate of the pull-down transistor N3 and then the pull-down transistor N3 is turned off, so that it is possible to prevent a leak current LA from flowing from the input/output terminal P to the ground potential VSS.

The configuration shown in FIG. 2 can be also used for the interface circuits 1B, 2A, 2B, 3A, and 3B shown in FIG. 1.

### Second Embodiment

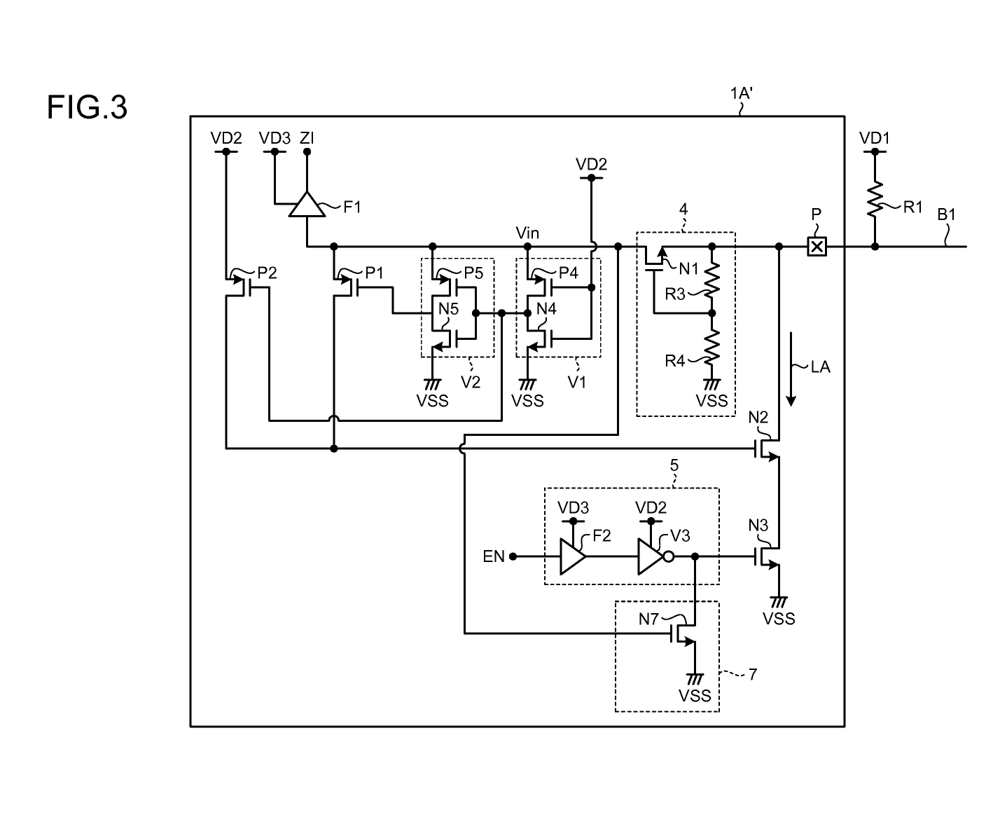

FIG. 3 is a circuit diagram illustrating a schematic configuration of an interface circuit 1A′ according to a second embodiment.

In FIG. 3, a leak-cut circuit 7 is provided in the interface circuit 1A′ instead of the leak-cut circuit 6 shown in FIG. 2. The leak-cut transistor N7 is provided in the leak-cut circuit 7. The input voltage Vin is input to the gate of the leak-cut transistor N7. The gate of the leak-cut transistor N7 can be connected to, for example, a drain of the transfer transistor N1.

Thereafter, as the input voltage Vin is input to the gate of the leak-cut transistor N7, the leak-cut transistor N7 is turned on. Furthermore, when the internal power supply potential VD2 is shut down, the output of the inverter V3 is in a high impedance state. Accordingly, the ground potential VSS is applied to the gate of the pull-down transistor N3 and then the pull-down transistor N3 is turned off, so that it is possible to prevent the leak current LA from flowing from the input/output terminal P to the ground potential VSS.

### Third Embodiment

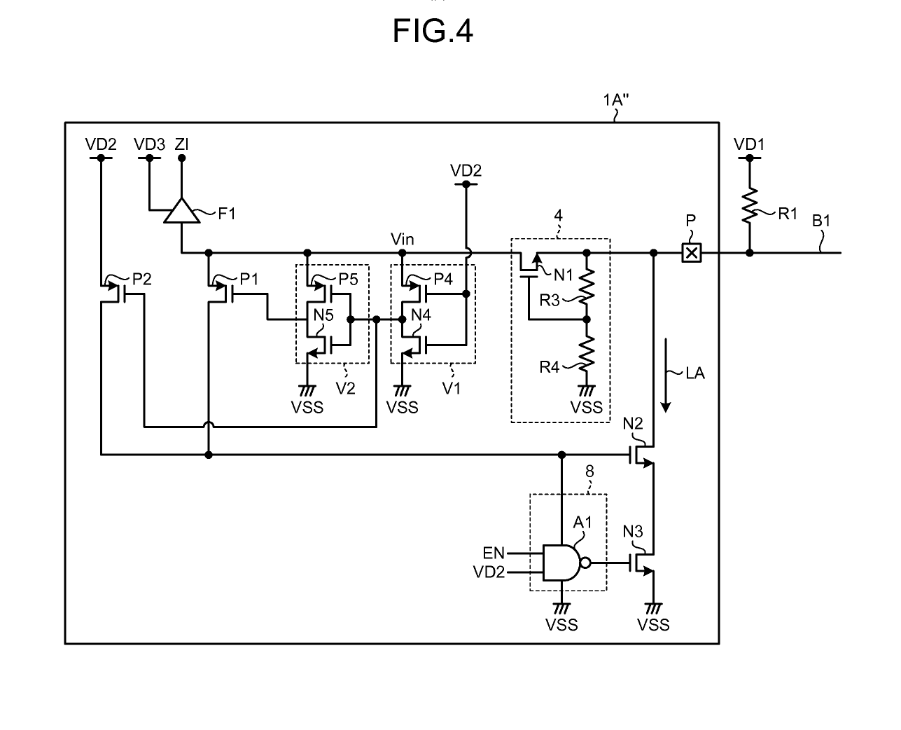

FIG. 4 is a circuit diagram illustrating a schematic configuration of an interface circuit 1A″ according to a third embodiment.

In FIG. 4, a mode switching circuit 8 is provided in the interface circuit 1A″ instead of the mode switching circuit 5 and the leak-cut circuit 6 shown in FIG. 2. A NAND circuit A1 is provided in the mode switching circuit 8. The enable signal EN is input to a first input terminal of the NAND circuit A1 and the internal power supply potential VD2 is input to a second input terminal of the NAND circuit A1. An output terminal of the NAND circuit A1 is connected to the gate of the pull-down transistor N3. Power feeding is made from the input voltage Vin to the NAND circuit A1.

In the output mode, the enable signal EN is set to a low level. When the internal power supply potential VD2 is supplied, an output of the NAND circuit A1 becomes a high level and the gate potential of the pull-down transistor N3 becomes a high level, thereby turning on the pull-down transistor N3. Accordingly, the input/output terminal P is pulled down to the ground potential VSS via the pull-down transistors N2 and N3.

Meanwhile, in the input mode, the enable signal EN is set to be a high level. When the internal power supply potential VD2 is supplied, the output of the NAND circuit A1 becomes a low level and then the pull-down transistor N3 is turned off. Accordingly, the input/output terminal P is pulled up to the external power supply potential VD1. In the input mode, when the internal power supply potential VD2 is shut down, the output of the NAND circuit A1 becomes a low level, and then the pull-down transistor N3 is turned off. Accordingly, it is possible to prevent the leak current LA from flowing from the input/output terminal P to the ground potential VSS.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An interface circuit comprising:
a first pull-down transistor that pulls down an input/output terminal;
a self-bias circuit that generates an input voltage based on a divided voltage that is generated by dividing an external voltage applied to the input/output terminal;
a second pull-down transistor that is connected in series to the first pull-down transistor;
a first control transistor that has power feeding made thereto from the input voltage and turns on the second pull-down transistor when an internal power supply is shut down;
a second control transistor that has power feeding made thereto from the internal power supply and turns on the second pull-down transistor when the internal power supply is supplied;
a mode switching circuit that has power feeding made thereto from the internal power supply and controls on and off of the first pull-down transistor based on an enable signal;
a leak-cut circuit that turns off the first pull-down transistor when the internal power supply is shut down;
a first inverter that has power feeding made thereto from the input voltage, the internal power supply input thereto, and controls a gate potential of the second control transistor; and
a second inverter that has power feeding made thereto from the input voltage, is connected in series to the first inverter, and controls a gate potential of the first control transistor.

2. The interface circuit according to claim 1, wherein the input/output terminal is connected to an external power supply potential via a resistor.

3. The interface circuit according to claim 2, wherein the input/output terminal is a pad electrode provided on a semiconductor chip.

4. The interface circuit according to claim 2, wherein the mode switching circuit switches an input mode in which the input/output terminal is pulled up to the external power supply potential and an output mode in which the input/output terminal is pulled down to a ground potential based on the enable signal.

5. The interface circuit according to claim 2, wherein the self-bias circuit includes
a transfer transistor that causes the external power supply potential to be applied to a source thereof and outputs the input voltage from a drain thereof, and
a voltage dividing resistor that divides the external power supply potential and applies a divided external power supply potential to a gate of the transfer transistor.

6. The interface circuit according to claim 2, comprising a buffer that outputs an output voltage that is lower-amplified than the external power supply potential based on the input voltage.

7. The interface circuit according to claim 1, wherein the leak-cut circuit includes
a leak-cut transistor that is connected between a gate of the first pull-down transistor and a ground potential, and
a third control transistor that applies the input voltage to a gate of the leak-cut transistor based on an output of the second inverter.

8. An interface circuit comprising:
a first pull-down transistor that pulls down an input/output terminal;
a mode switching circuit that controls on and off of the first pull-down transistor based on an enable signal; and
a leak-cut circuit that turns off the first pull-down transistor when a power supply of the mode switching circuit is shut down.

9. The interface circuit according to claim 8, comprising:
a self-bias circuit that generates an input voltage based on a divided voltage that is generated by dividing an applied voltage applied to the input/output terminal;
a second pull-down transistor that is connected in series to the first pull-down transistor;
a first control transistor that has power feeding made thereto from the input voltage and turns on the second pull-down transistor when the power supply of the mode switching circuit is shut down; and
a second control transistor that has a common power supply to the mode switching circuit and turns on the second pull-down transistor when the power supply of the mode switching circuit is supplied.

10. The interface circuit according to claim 9, wherein the leak-cut circuit includes a leak-cut transistor that controls a gate potential of the first pull-down transistor based on the input voltage such that the first pull-down transistor is turned off.

11. The interface circuit according to claim 8, wherein the input/output terminal is connected to an external power supply potential via a resistor.

12. The interface circuit according to claim 11, wherein the mode switching circuit switches an input mode in which the input/output terminal is pulled up to the external power supply potential and an output mode in which the input/output terminal is pulled down to a ground potential based on the enable signal.

13. The interface circuit according to claim 11, wherein the self-bias circuit includes
a transfer transistor that causes the external power supply potential to be applied to a source thereof and outputs the input voltage from a drain thereof, and
a voltage dividing resistor that divides the external power supply potential and applies a divided external power supply potential to a gate of the transfer transistor.

14. The interface circuit according to claim 11, comprising a buffer that outputs an output voltage that is lower-amplified than the external power supply potential based on the input voltage.

15. An interface circuit comprising:
a first pull-down transistor that pulls down an input/output terminal;
a self-bias circuit that generates an input voltage based on a divided voltage that is generated by dividing an applied voltage applied to the input/output terminal;
a second pull-down transistor that is connected in series to the first pull-down transistor;
a first control transistor that has power feeding made thereto from the input voltage and turns on the second pull-down transistor when an internal power supply is shut down;
a second control transistor that has power feeding made thereto from the internal power supply and turns on the second pull-down transistor when the internal power supply is supplied; and
a logic circuit that has power feeding made thereto from a gate potential of the second pull-down transistor and controls on and off of the first pull-down transistor based on a result of a logical operation between an enable signal and the internal power supply.

16. The interface circuit according to claim 15, wherein the input/output terminal is connected to an external power supply potential via a resistor.

17. The interface circuit according to claim 16, wherein the input/output terminal is a pad electrode provided on a semiconductor chip.

18. The interface circuit according to claim 16, wherein the enable signal switches an input mode in which the input/output terminal is pulled up to the external power supply potential and an output mode in which the input/output terminal is pulled down to a ground potential.

19. The interface circuit according to claim 16, wherein the self-bias circuit includes
a transfer transistor that causes the external power supply potential to be applied to a source thereof and outputs the input voltage from a drain thereof, and
a voltage dividing resistor that divides the external power supply potential and applies a divided external power supply potential to a gate of the transfer transistor.

20. The interface circuit according to claim 16, comprising a buffer that outputs an output voltage that is lower-amplified than the external power supply potential based on the input voltage.
